(19) United States
(12) Patent Application Publication
(10) Pub. No.: US 2023/0031443 A1
(43) Pub. Date: Feb. 2, 2023

(54) WAFER CLAMP HARD BURL PRODUCTION AND REFURBISHMENT

(71) Applicant: ASML Holding N.V., Veldhoven (NL)

(72) Inventors: Matthew LIPSON, Stamford, CT (US); Mehmet Ali AKBAS, Cheshire, CT (US); Tammo UITTERDIJK, Wilton, CT (US); Fei ZHAO, New Canaan, CT (US)

(73) Assignee: ASML Holding N.V., Veldhoven (NL)

(21) Appl. No.: 17/788,806

(22) PCT Filed: Dec. 8, 2020
(86) PCT No.: PCT/EP2020/085107

§ 371 Date: Jun. 24, 2022

Related U.S. Application Data
(60) Provisional application No. 62/953,730, filed on Dec. 26, 2019.

(51) Int. Cl. G03F 7/20

(52) U.S. Cl. CPC G03F 7/707; G03F 7/70725

(57) ABSTRACT

Systems, apparatuses, and methods are provided for manufacturing a wafer clamp having hard burls. The method can include providing a first layer that includes a first surface. The method can further include forming a plurality of burls over the first surface of the first layer. The forming of the plurality of burls can include forming a subset of the plurality of burls to a hardness of greater than about 6.0 gigapascals (GPa).

### CROSS-REFERENCE TO RELATED APPLICATIONS

This application claims priority of U.S. Provisional Pat. Application No. 62/953,730, which was filed on Dec. 26, 2019, and which is incorporated herein in its entirety by reference.

### FIELD

The present disclosure relates to substrate tables and methods for forming burls and nanostructures on substrate table surfaces.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is interchangeably referred to as a mask or a reticle, can be used to generate a circuit pattern to be formed on an individual layer of the IC being formed. This pattern can be transferred onto a target portion (e.g., including part of, one, or several dies) on a substrate (e.g., a silicon wafer). Transfer of the pattern is typically via imaging onto a layer of radiation-sensitive material (e.g., resist) provided on the substrate. In general, a single substrate will contain a network of adjacent target portions that are successively patterned. Traditional lithographic apparatuses include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

Extreme ultraviolet (EUV) light, for example, electromagnetic radiation having wavelengths of around 50 nanometers (nm) or less (also sometimes referred to as soft x-rays), and including light at a wavelength of about 13 nm, can be used in or with a lithographic apparatus to produce extremely small features in substrates, for example, silicon wafers. Methods to produce EUV light include, but are not necessarily limited to, converting a material that has an element, for example, xenon (Xe), lithium (Li), or tin (Sn), with an emission line in the EUV range to a plasma state. For example, in one such method called laser produced plasma (LPP), the plasma can be produced by irradiating a target material, which is interchangeably referred to as fuel in the context of LPP sources, for example, in the form of a droplet, plate, tape, stream, or cluster of material, with an amplified light beam that can be referred to as a drive laser. For this process, the plasma is typically produced in a sealed vessel, for example, a vacuum chamber, and monitored using various types of metrology equipment.

Another lithographic system is an interferometric lithographic system where there is no patterning device. Rather, an interferometric lithographic system splits a light beam into two beams and causes the two beams to interfere at a target portion of the substrate through the use of a reflection system. The interference causes lines to be formed at the target portion of the substrate.

During lithographic operation, different processing steps may require different layers to be sequentially formed on the substrate. Accordingly, it can be necessary to position the substrate relative to prior patterns formed thereon with a high degree of accuracy. Generally, alignment marks are placed on the substrate to be aligned and are located with reference to a second object. A lithographic apparatus may use an alignment apparatus for detecting positions of the alignment marks and for aligning the substrate using the alignment marks to ensure accurate exposure from a mask. Misalignment between the alignment marks at two different layers is measured as overlay error.

In order to monitor the lithographic process, parameters of the patterned substrate are measured. Parameters may include, for example, the overlay error between successive layers formed in or on the patterned substrate and critical linewidth of developed photosensitive resist. This measurement can be performed on a product substrate, a dedicated metrology target, or both. There are various techniques for making measurements of the microscopic structures formed in lithographic processes, including the use of scanning electron microscopes and various specialized tools. A fast and non-invasive form of a specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Spectroscopic scatterometers direct a broadband radiation beam onto the substrate and measure the spectrum (intensity as a function of wavelength) of the radiation scattered into a particular narrow angular range. By contrast, angularly resolved scatterometers use a monochromatic radiation beam and measure the intensity of the scattered radiation as a function of angle.

Such optical scatterometers can be used to measure parameters, such as critical dimensions of developed photosensitive resist or overlay error between two layers formed in or on the patterned substrate. Properties of the substrate can be determined by comparing the properties of an illumination beam before and after the beam has been reflected or scattered by the substrate.

It is desirable to dictate and maintain tribological properties (e.g., friction, hardness, wear) on a surface of a substrate table. In some instances, a wafer clamp may be disposed on the surface of the substrate table. A substrate table, or a wafer clamp attached thereto, has a surface level tolerance that can be difficult to meet because of precision requirements of lithographic and metrology processes. Wafers (e.g., semiconductor substrates), being relatively thin (e.g., < 1 millimeter (mm) thick) compared to a width of its surface area (e.g., > 100 mm wide), are particularly sensitive to unevenness of the substrate table. Additionally, ultra-smooth surfaces in contact may become stuck together, which may present a problem when a substrate must be disengaged from the substrate table. To reduce the smoothness of the surface that interfaces with the wafer, the surface of the substrate table or wafer clamp may include glass burls formed by patterning and etching of a glass substrate. However, these glass burls only have a hardness of about 6.0 gigapascals (GPa) and, as a result, can crack during operation of the lithographic apparatus, crushed by particles jammed into the glass burls by the clamped wafers.

### SUMMARY

The present disclosure describes various aspects of systems, apparatuses, and methods for substrate tables and wafer clamps that include hard burls. A hard burl can be a burl having a hardness of greater than about 6.0 gigapascals (GPa) and, in some aspects, greater than about 20.0 GPa. These hard burls provide for increased wear resistance and frictional properties that are conducive to engaging and disengaging a substrate during operation of a lithographic apparatus without cracking.

In some aspects, the present disclosure describes a method for manufacturing an apparatus. The method can include providing a first layer that includes a first surface. The method can further include forming a plurality of burls over the first surface of the first layer. The forming of the plurality of burls can include forming a subset of the plurality of burls to a hardness of greater than about 6.0 GPa.

In some aspects, the present disclosure describes another method for manufacturing an apparatus. The method can include receiving a wafer clamp. The wafer clamp can include: a first layer that includes a first surface; and a first plurality of burls disposed over the first surface of the first layer. The method can further include removing the first plurality of burls. The method can further include forming a second plurality of burls over the first surface of the first layer. The forming of the second plurality of burls can include forming a subset of the second plurality of burls to a hardness of greater than about 6.0 GPa.

In some aspects, the present disclosure describes an apparatus. The apparatus can include a first layer that includes a first surface. The apparatus can further include a plurality of burls disposed over the first surface of the first layer, wherein a hardness of a subset of the plurality of burls is greater than about 6.0 GPa.

Further features, as well as the structure and operation of various aspects, are described in detail below with reference to the accompanying drawings. It is noted that the disclosure is not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the aspects of this disclosure and to enable a person skilled in the relevant art(s) to make and use the aspects of this disclosure.

FIG. 1A is a schematic illustration of an example reflective lithographic apparatus according to some aspects of the present disclosure.

FIG. 1B is a schematic illustration of an example transmissive lithographic apparatus according to some aspects of the present disclosure.

FIG. 2 is a more detailed schematic illustration of the reflective lithographic apparatus shown in FIG. 1A according to some aspects of the present disclosure.

FIG. 3 is a schematic illustration of an example lithographic cell according to some aspects of the present disclosure.

FIG. 4 is a schematic illustration of an example substrate stage according to some aspects of the present disclosure.

FIG. 5 is a cross-sectional illustration of a region of an example clamp according to some aspects of the present disclosure.

FIG. 6 is a cross-sectional illustration of a region of another example clamp according to some aspects of the present disclosure.

FIG. 7 is an example method for manufacturing an apparatus according to some aspects of the present disclosure or portion(s) thereof.

FIG. 8 is another example method for manufacturing an apparatus according to some aspects of the present disclosure or portion(s) thereof.

The features and advantages of the present disclosure will become more apparent from the detailed description set forth below when taken in conjunction with the drawings, in which like reference characters identify corresponding elements throughout. In the drawings, unless otherwise indicated, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) merely describe the present disclosure. The scope of the disclosure is not limited to the disclosed embodiment(s). The breadth and scope of the disclosure are defined by the claims appended hereto and their equivalents.

The embodiment(s) described, and references in the specification to “one embodiment,” “an embodiment,” “an example embodiment,” etc., indicate that the embodiment(s) described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Spatially relative terms, such as “beneath,” “below,” “lower,” “above,” “on,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., ±10%, ±20%, or ±30% of the value).

### Overview

Conventional lithographic apparatuses that use an EUV radiation source typically require the EUV radiation beam path, or at least substantial parts of it, to be kept in vacuum during a lithographic operation. In such vacuum regions of the lithographic apparatus, an electrostatic clamp can be used to clamp an object, such as a patterning device (e.g., a mask or reticle) or a substrate (e.g., a wafer), to a structure of the lithographic apparatus, such as a patterning device table or a substrate table, respectively. A conventional electrostatic clamp can include an electrode at one surface of the clamp with a plurality of burls disposed on the opposite surface of the clamp. As the clamp is energized (e.g., using a clamping voltage) and pulls the reticle or wafer in contact with the burls, the conductive burl tops can be at a different potential than the reticle or wafer backside. At the moment of contact, this potential difference causes a discharge mechanism as the two potentials are equalized. This discharge mechanism can cause material transfer and particle generation and ultimately result in damage to the reticle or wafer, the clamp, or a combination thereof. Further, conventional wafer clamps typically include glass burls formed by patterning and etching of a glass substrate. These glass burls only have a hardness of about 6.0 GPa and, as a result, can crack during operation of the lithographic apparatus, crushed by particles jammed into the glass burls by the clamped wafers.

In contrast to these conventional systems, the present disclosure provides a method for manufacturing a wafer clamp, or an electrostatic clamp, that includes hard burls. The hard burls can be manufactured from a material such as diamond-like carbon (DLC), aluminum nitride (AlN), silicon nitride (SiN), or chromium nitride (CrN). The hard burls can have a hardness greater than about 6.0 GPa and, in some instances, greater than about 20.0 GPa. Additionally, the present disclosure provides a method for reworking a wafer clamp, or an electrostatic clamp, that has been returned from the field with broken glass burls. The method includes removing the glass burls and fabricating a layer of hard burls on a surface of the wafer clamp or electrostatic clamp.

In some aspects, the present disclosure provides for a method for manufacturing a clamp that includes, among other aspects, the following three operations.

1. Start with a clamp with the dielectric layer (e.g., a glass substrate, a borosilicate glass substrate, an alkaline earth boro-aluminosilicate) thinned to its final thickness of about 100 micrometers (microns). In some aspects where a clamp has been returned from the field, this operation can include grinding and polishing off the glass burls. In some aspects where the dielectric layer is thinned to a thickness of less than about 100 microns, this operation can also include depositing a layer (e.g., about 5.0 microns) of silicon dioxide (SiO₂) via vapor deposition, such as plasma enhanced chemical vapor deposition (PECVD).

2. Deposit around 10.0 microns of a hard and etchable material, such as DLC, Cr, CrN, SiN, or AlN, and then pattern and etch the deposited layer to form the hard burls. For example, flash the dielectric layer with Cr to form an adhesion layer, deposit 10.0 microns of DLC on the Cr adhesion layer, coat the DLC layer with Cr, create a burl pattern for the hard burls (e.g., pattern resist on top of the Cr in the shape of burls), and pattern the Cr. Subsequently, use a dry etch process to pattern the DLC before using a final wet chemical etch to pattern the Cr adhesion layer and remove the Cr from the top of the hard burls. Alternatively, perform an isotropic oxygen etch (e.g., oxygen plasma ash), and perform a Cr etch to form the hard burls. In some aspects, a similar process may be utilized if the hard burls are formed out of CrN, AlN, or another suitable material.

3. Coat the hard burls with CrN and then pattern and etch the coated hard burls to create electrically conductive burl tops and, in some instances, electrical connections along the structured surfaces between those burl tops.

There are many advantages and benefits to the clamps disclosed herein. For example, the present disclosure provides for wafer clamps and electrostatic clamps that include hard burls having a hardness of greater than about 6.0 gigapascals (GPa) and, in some aspects, greater than about 20.0 GPa. These hard burls provide for increased wear resistance over traditional glass burls and frictional properties that are conducive to engaging and disengaging a substrate or patterning device during operation of a lithographic apparatus without cracking or breaking. Further, the present disclosure facilitates the re-working of clamps with broken burls that have been returned from the field. As a result of the techniques described in the present disclosure, the related lithographic apparatuses can be returned to service faster, cheaper, and more reliably than with previous techniques. In some aspects, the present disclosure facilitates the return of re-worked clamps to the field with much harder burls that will not so readily break during lithographic operation.

Before describing such aspects in more detail, however, it is instructive to present an example environment in which aspects of the present disclosure can be implemented.

### Example Lithographic Systems

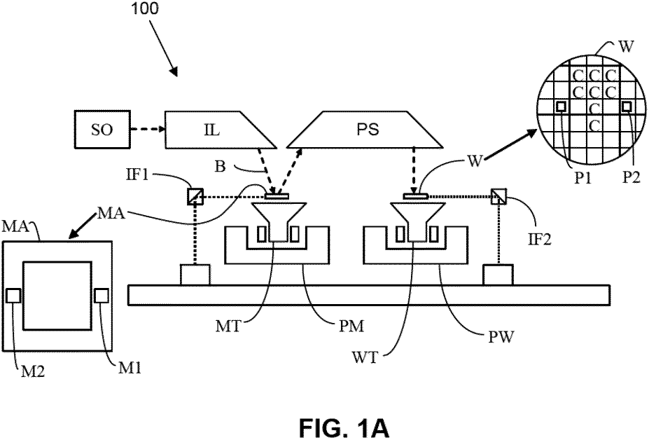

FIGS. 1A and 1B are schematic illustrations of a lithographic apparatus 100 and lithographic apparatus 100', respectively, in which aspects of the present disclosure can be implemented. Lithographic apparatus 100 and lithographic apparatus 100' each include the following: an illumination system (illuminator) IL configured to condition a radiation beam B (for example, deep ultra violet (DUV) radiation or extreme ultra violet (EUV) radiation); a support structure (for example, a mask table) MT configured to support a patterning device (for example, a mask, a reticle, or a dynamic patterning device) MA and connected to a first positioner PM configured to accurately position the patterning device MA; and, a substrate holder such as a substrate table (for example, a wafer table) WT configured to hold a substrate (for example, a resist coated wafer) W and connected to a second positioner PW configured to accurately position the substrate W. Lithographic apparatuses 100 and 100' also have a projection system PS configured to project a pattern imparted to the radiation beam B by patterning device MA onto a target portion (for example, including one or more dies) C of the substrate W. In lithographic apparatus 100, the patterning device MA and the projection system PS are reflective. In lithographic apparatus 100', the patterning device MA and the projection system PS are transmissive.

The illumination system IL can include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatuses 100 and 100', and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable, as required. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The patterning device MA can be transmissive (as in lithographic apparatus 100' of FIG. 1B) or reflective (as in lithographic apparatus 100 of FIG. 1A). Examples of patterning devices MA include reticles, masks, programmable mirror arrays, or programmable LCD panels. Masks include mask types such as binary, alternating phase shift, or attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B, which is reflected by a matrix of small mirrors.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100' can be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

The lithographic apparatus can also be of a type wherein at least a portion of the substrate can be covered by a liquid having a relatively high refractive index, e.g., water, so as to fill a space between the projection system and the substrate. An immersion liquid can also be applied to other spaces in the lithographic apparatus, for example, between the mask and the projection system. Immersion techniques provide for increasing the numerical aperture of projection systems. The term “immersion” as used herein does not mean that a structure, such as a substrate, must be submerged in liquid, but rather only means that liquid is located between the projection system and the substrate during exposure.

Referring to FIGS. 1A and 1B, the illumination system IL receives a radiation beam B from a radiation source SO. The radiation source SO and the lithographic apparatus 100, 100' can be separate physical entities, for example, when the radiation source SO is an excimer laser. In such cases, the radiation source SO is not considered to form part of the lithographic apparatus 100 or 100', and the radiation beam B passes from the radiation source SO to the illumination system IL with the aid of a beam delivery system BD (in FIG. 1B) including, for example, suitable directing mirrors and/or a beam expander. In other cases, the radiation source SO can be an integral part of the lithographic apparatus 100, 100', for example, when the radiation source SO is a mercury lamp. The radiation source SO and the illuminator IL, together with the beam delivery system BD, if required, can be referred to as a radiation system.

The illumination system IL can include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illumination system IL can include various other components (in FIG. 1B), such as an integrator IN and a radiation collector (for example, a condenser) CO. The illumination system IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device MA. After being reflected from the patterning device MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device MA with respect to the path of the radiation beam B. Patterning device MA and substrate W can be aligned using mask alignment marks M1, M2 and substrate alignment marks P1, P2.

Referring to FIG. 1B, the radiation beam B is incident on the patterning device MA, which is held on the support structure MT, and is patterned by the patterning device MA. Having traversed the patterning device MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image MP' of the mask pattern MP, where image MP' is formed by diffracted beams produced from the mask pattern MP by radiation from the intensity distribution, onto a resist layer coated on the substrate W. For example, the mask pattern MP can include an array of lines and spaces. A diffraction of radiation at the array and different from zeroth-order diffraction generates diverted diffracted beams with a change of direction in a direction perpendicular to the lines. Undiffracted beams (e.g., so-called zeroth-order diffracted beams) traverse the pattern without any change in propagation direction. The zeroth-order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth-order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture, by means of a lens or lens group L, not only the zeroth-order diffracted beams, but also first-order or first- and higher-order diffracted beams (not shown). In some aspects, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the substrate W to create an image of the mask pattern MP at highest possible resolution and process window (e.g., usable depth of focus in combination with tolerable exposure dose deviations). In some aspects, astigmatism aberration can be reduced by providing radiation poles (not shown) in opposite quadrants of the illumination system pupil IPU. Further, in some aspects, astigmatism aberration can be reduced by blocking the zeroth-order beams in the pupil conjugate PPU of the projection system associated with radiation poles in opposite quadrants. This is described in more detail in U.S. Pat. No. 7,511,799, issued Mar. 31, 2009, which is incorporated by reference herein in its entirety.

With the aid of the second positioner PW and position sensor IF (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the patterning device MA with respect to the path of the radiation beam B (for example, after mechanical retrieval from a mask library or during a scan).

In general, movement of the support structure MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the support structure MT can be connected to a short-stroke actuator only or can be fixed. Patterning device MA and substrate W can be aligned using mask alignment marks M1, M2, and substrate alignment marks P1, P2. Although the substrate alignment marks (as illustrated) occupy dedicated target portions, they can be located in spaces between target portions (e.g., scribe-lane alignment marks). Similarly, in situations in which more than one die is provided on the patterning device MA, the mask alignment marks can be located between the dies.

Support structure MT and patterning device MA can be in a vacuum chamber V, where an in-vacuum robot IVR can be used to move patterning devices such as a mask in and out of vacuum chamber. Alternatively, when support structure MT and patterning device MA are outside of the vacuum chamber, an out-of-vacuum robot can be used for various transportation operations, similar to the in-vacuum robot IVR. In some instances, both the in-vacuum and out-of-vacuum robots need to be calibrated for a smooth transfer of any payload (e.g., mask) to a fixed kinematic mount of a transfer station.

The lithographic apparatuses 100 and 100' can be used in at least one of the following modes:
1. In step mode, the support structure MT and the substrate table WT are kept essentially stationary, while an entire pattern imparted to the radiation beam B is projected onto a target portion C at one time (e.g., a single static exposure). The substrate table WT is then shifted in the X and/or Y direction so that a different target portion C can be exposed.
2. In scan mode, the support structure MT and the substrate table WT are scanned synchronously while a pattern imparted to the radiation beam B is projected onto a target portion C (e.g., a single dynamic exposure). The velocity and direction of the substrate table WT relative to the support structure (for example, mask table) MT can be determined by the (de-)magnification and image reversal characteristics of the projection system PS.
3. In another mode, the support structure MT is kept substantially stationary holding a programmable patterning device MA, and the substrate table WT is moved or scanned while a pattern imparted to the radiation beam B is projected onto a target portion C. A pulsed radiation source SO can be employed and the programmable patterning device is updated as required after each movement of the substrate table WT or in between successive radiation pulses during a scan. This mode of operation can be readily applied to maskless lithography that utilizes a programmable patterning device MA, such as a programmable mirror array.

Combinations and/or variations on the described modes of use or entirely different modes of use can also be employed.

In a further aspect, lithographic apparatus 100 includes an EUV source, which is configured to generate a beam of EUV radiation for EUV lithography. In general, the EUV source is configured in a radiation system, and a corresponding illumination system is configured to condition the EUV radiation beam of the EUV source.

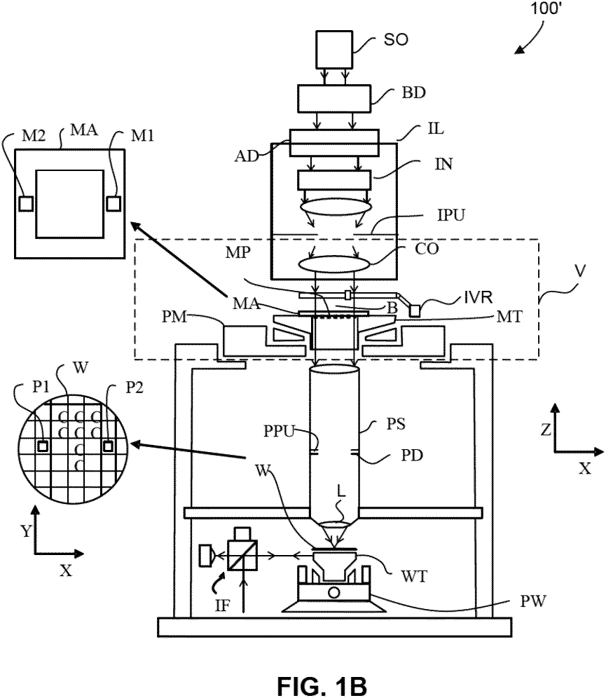

FIG. 2 shows the lithographic apparatus 100 in more detail, including the radiation source (for example, a source collector apparatus) SO, the illumination system IL, and the projection system PS. The radiation source SO is constructed and arranged such that a vacuum environment can be maintained in an enclosing structure 220. The radiation source SO includes a source chamber 211 and a collector chamber 212 and is configured to produce and transmit EUV radiation. EUV radiation can be produced by a gas or vapor, for example xenon (Xe) gas, lithium (Li) vapor, or tin (Sn) vapor in which an EUV radiation emitting plasma 210 is created to emit radiation in the EUV range of the electromagnetic spectrum. The EUV radiation emitting plasma 210, at least partially ionized, can be created by, for example, an electrical discharge or a laser beam. Partial pressures of, for example, 10 pascals (Pa) of Xe gas, Li vapor, Sn vapor, or any other suitable gas or vapor can be used for efficient generation of the radiation. In some aspects, a plasma of excited tin is provided to produce EUV radiation.

The radiation emitted by the EUV radiation emitting plasma 210 is passed from the source chamber 211 into the collector chamber 212 via an optional gas barrier or contaminant trap 230 (in some cases also referred to as contaminant barrier or foil trap), which is positioned in or behind an opening in source chamber 211. The contaminant trap 230 can include a channel structure. Contamination trap 230 can also include a gas barrier or a combination of a gas barrier and a channel structure. The contaminant trap 230 further indicated herein at least includes a channel structure.

The collector chamber 212 can include a radiation collector (for example, a collector optic) CO, which can be a so-called grazing incidence collector. Radiation collector CO has an upstream radiation collector side 251 and a downstream radiation collector side 252. Radiation that traverses radiation collector CO can be reflected off a grating spectral filter 240 to be focused in a virtual source point IF. The virtual source point IF is commonly referred to as the intermediate focus, and the source collector apparatus is arranged such that the virtual source point IF is located at or near an opening 219 in the enclosing structure 220. The virtual source point IF is an image of the EUV radiation emitting plasma 210. Grating spectral filter 240 is used in particular for suppressing infrared (IR) radiation.

Subsequently the radiation traverses the illumination system IL, which can include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the radiation beam 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown may generally be present in illumination system IL and projection system PS. Optionally, the grating spectral filter 240 can be present depending upon the type of lithographic apparatus. Further, there can be more mirrors present than those shown in the FIG. 2. For example, there can be one to six additional reflective elements present in the projection system PS than shown in FIG. 2.

Radiation collector CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a radiation collector CO of this type is preferably used in combination with a discharge produced plasma (DPP) source.

### Example Lithographic Cell

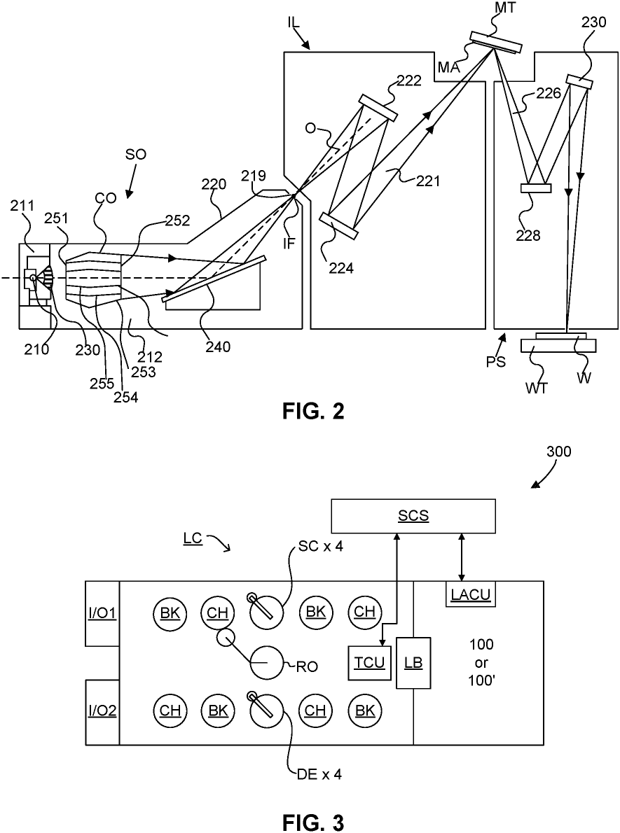

FIG. 3 shows a lithographic cell 300, also sometimes referred to a lithocell or cluster. Lithographic apparatus 100 or 100' can form part of lithographic cell 300. Lithographic cell 300 can also include one or more apparatuses to perform pre- and post-exposure processes on a substrate. For example, these apparatuses can include spin coaters SC to deposit resist layers, developers DE to develop exposed resist, chill plates CH, and bake plates BK. A substrate handler (for example, a robot) RO picks up substrates from input/output ports I/O1, I/O2, moves them between the different process apparatuses and delivers them to the loading bay LB of the lithographic apparatus 100 or 100'. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Example Substrate Stage

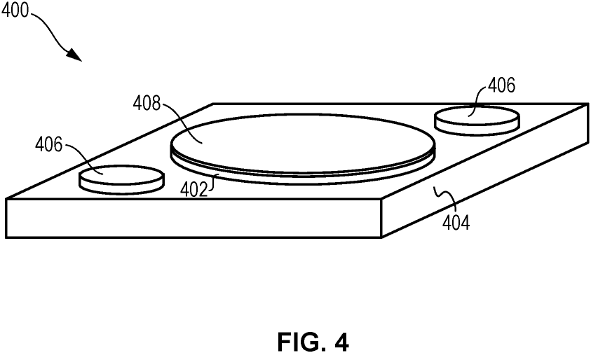

FIG. 4 shows a schematic illustration of an example substrate stage 400, according to some aspects of the present disclosure. In some aspects, the example substrate stage 400 can include a substrate table 402, a support block 404, one or more sensor structures 406, any other suitable component, or any combination thereof. In some aspects, substrate table 402 comprises a clamp (e.g., a wafer clamp, a reticle clamp, an electrostatic clamp) to hold a substrate 408. In some aspects, each of one or more sensor structures 406 comprises a transmission image sensor (TIS) plate. The TIS plate is a sensor unit that comprises one or more sensors and/or markers for use in a TIS sensing system used for accurate positioning of the wafer relative to the position of a projection system (e.g., projection system PS described with reference to FIGS. 1A, 1B, and 2) and a mask (e.g., patterning device MA described with reference to FIGS. 1A, 1B, and 2) of a lithographic apparatus (e.g., lithographic apparatus 100 and lithographic apparatus 100' described with reference to FIGS. 1A, 1B, and 2). While TIS plates are shown here for illustration, aspects herein are not limited to any particular sensor. Substrate table 402 is disposed on support block 404. One or more sensor structures 406 are disposed on support block 404.

In some aspects, substrate 408 can be disposed on substrate table 402 when the example substrate stage 400 supports the substrate 408.

The terms “flat,” “flatness” or the like can be used herein to describe structures in relation to a general plane of a surface. For example, a bent or unleveled surface can be one that does not conform to a flat plane. Protrusions and recesses on a surface can also be characterized as deviations from a “flat” plane.

The terms “smooth,” “roughness” or the like, can be used herein to refer to a local variation, microscopic deviations, graininess, or texture of a surface. For example, the term “surface roughness” can refer to microscopic deviations of the surface profile from a mean line or plane. The deviations are generally measured (in unit of length) as an amplitude parameter, such as root mean squared (RMS) or arithmetical mean deviation (Ra) (e.g., 1 nm RMS).

In some aspects, the surface of the substrate tables mentioned above (e.g., substrate table WT in FIGS. 1A and 1B, substrate table 402 in FIG. 4) can be flat or burled. When the surface of a substrate table is flat, any particulates or contaminants stuck between the substrate table and a wafer will cause the contaminant to print through the wafer, causing lithography errors in its vicinity. Consequently, contaminants reduce device yield rates and increase production costs.

Disposing burls on substrate tables help to reduce the undesirable effects of a flat substrate table. When a wafer is clamped to a burled substrate table, empty spaces are available in the regions where the wafer does not contact the substrate table. The empty spaces function as pockets for contaminants so as to prevent printing errors. Another advantage is that contaminants located on the burls are more likely to become crushed due to the increased load caused by the burls. Crushing contaminants helps mitigate print-through errors as well. In some aspects, the combined surface area of the burls can be approximately one percent to five percent of the surface area of the substrate table. Here, surface area of the burls refers to the surfaces that come into contact with the wafer (e.g., not including the side walls); and surface area of the substrate table refers to the span of surface of the substrate table where the burls reside (e.g., not including the lateral or back side of the substrate table). When the wafer is clamped onto the burled substrate table, the load is increased by 100 fold as compared to a flat substrate table, which is enough to crush most contaminants. Though the example here uses a substrate table, the example is not intended to be limiting. For example, aspects of the present disclosure can be implemented on reticle tables, for a variety of clamping structures (e.g., electrostatic clamps, clamping membranes), and in a variety of lithographic systems (e.g., EUV, DUV).

In some aspects, the burl-to-wafer interface governs the functional performance of the substrate table. When the surface of a substrate table is smooth, an adhesion force can develop between the smooth surface of the substrate table and the smooth surface of a wafer. The phenomenon where two smooth surfaces in contact cling together is known as wringing. Wringing can cause issues (e.g., overlay issues) in device fabrication due to high friction and in-plane stresses in the wafer (it is optimal to have the wafer glide easily during alignment).

Moreover, it has been observed that burled surfaces of substrate tables are susceptible to unusually rapid wear, particularly at the edges away from the center of the substrate table (e.g., uneven wear). Uneven wear causes a wafer to bend when clamped to the substrate table, which in turn reduces accuracy of lithographic placement of device structures, overlay drift over time, and the like. And the overall wear can reintroduce wringing issues and lead to decrease in imaging performance due to change in global shape of clamping surface.

To increase the hardness of the burl-top surface and prevent frictional wear of that surface, the present disclosure provides for hard burls. As referred to herein, the term “hard” can refer to a hardness of greater than about 6.0 GPa and, in some aspects, greater than about 20.0 GPa; and the term “hard burl” can be a burl having a hardness of greater than about 6.0 GPa and, in some aspects, greater than about 20.0 GPa. For example, the hard burls can be of a material selected from the group consisting of DLC, AlN, SiN, CrN, or any other suitable material or combination thereof.

### Example Surfaces Having Hard Burls

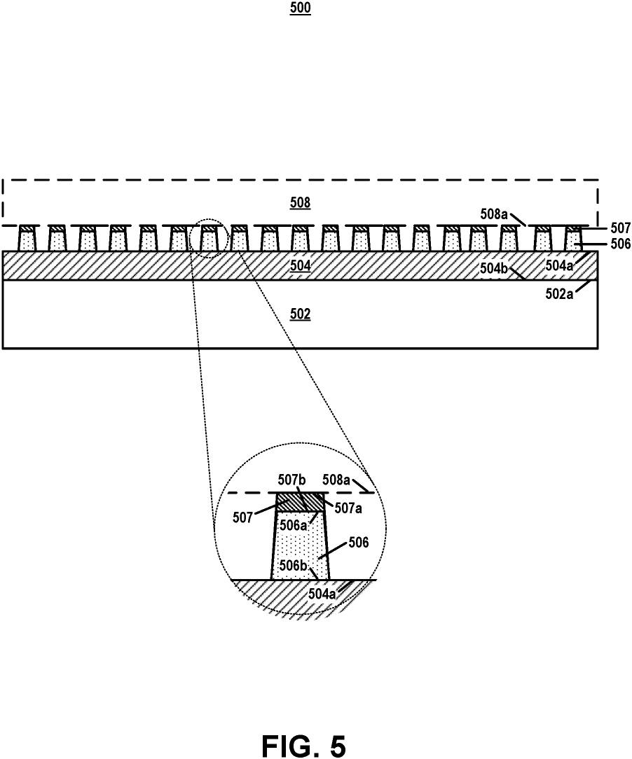

FIG. 5 shows a cross-sectional illustration of a region of an example clamp 500 (e.g., a wafer clamp, a reticle clamp, an electrostatic clamp). The example clamp 500 can include a first layer 502 (e.g., a glass substrate, a borosilicate glass substrate, an alkaline earth boro-aluminosilicate substrate, a layer of SiO₂) including a first surface 502a.

The example clamp 500 can further include a second layer 504 (e.g., an adhesion layer such as a layer of Cr, Al, Si, or any other suitable material) including a second surface 504a and a third surface 504b opposite the second surface 504a. The third surface 504b of the second layer 504 can be disposed on the first surface 502a of the first layer 502. In some aspects, the second layer 504 can be patterned as a final, or near final, step.

The example clamp 500 can further include a plurality of burls 506 (e.g., DLC burls) disposed over the first surface 502a of the first layer 502. For example, the plurality of burls 506 can be disposed on the second surface 504a of the second layer 504. A hardness of a subset of the plurality of burls 506 can be greater than about 6.0 GPa and, in some instances, greater than about 10.0 GPa, about 15.0 GPa, or even about 20.0 GPa. A thickness of the plurality of burls 506 can be greater than about 2.0 microns and, in some instances, greater than about 5.0 microns, 7.5 microns, or even about 10.0 microns. A radius of each of the plurality of burls 506 can be about 200.0 microns. In some aspects, the plurality of burls 506 can include at least about thirty thousand burls. In some aspects, the plurality of burls 506 can be formed by patterning and etching a third layer (e.g., a DLC layer) to form the plurality of burls 506.

The example clamp 500 can further include a plurality of burl tops 507 (e.g., CrN burl tops) disposed over the plurality of burls 506. The plurality of burl tops 507 can be formed by patterning and etching a fourth layer (e.g., a CrN layer) to form the plurality of burl tops 507. In some aspects, the plurality of burls 506, the plurality of burl tops 507, or both can be electrically conductive.

Each burl in the plurality of burls 506 can include a fourth surface 506a and a fifth surface 506b opposite the fourth surface 506a. The fifth surface 506b of the burl can be disposed on the second surface 504a of the second layer 504. Each burl top in the plurality of burl tops 507 can include a sixth surface 507a and a seventh surface 507b opposite the sixth surface 507a. The seventh surface 507b of the burl top can be disposed on the fourth surface 506a of the burl.

Optionally, an object 508 (e.g., a wafer W or a patterning device MA) can be positioned over the plurality of burl tops 507. For example, an eighth surface 508a of the object 508 can be removable disposed (e.g., placed, positioned) on the sixth surface 507a of one or more of the plurality of burl tops 507.

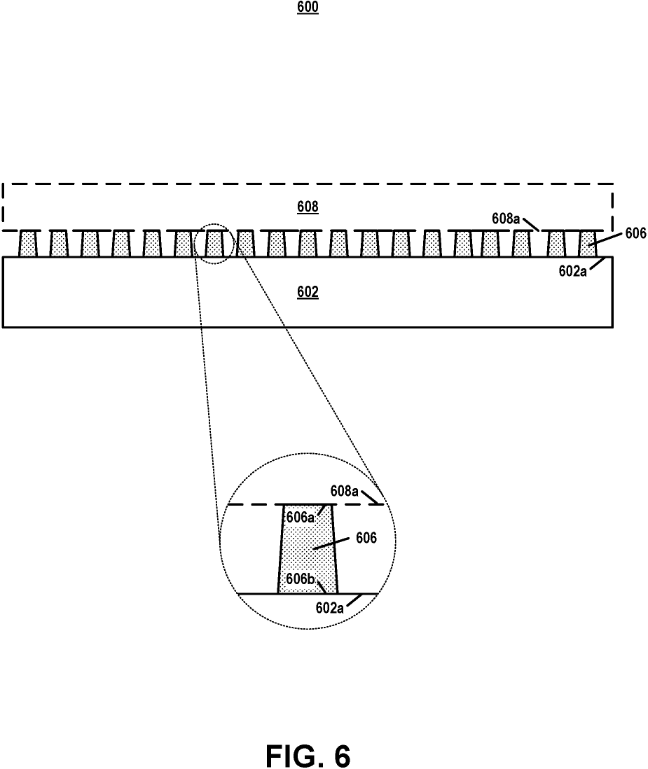

FIG. 6 shows a cross-sectional illustration of a region of an example clamp 600 (e.g., a wafer clamp, a reticle clamp, an electrostatic clamp). The example clamp 600 can include a first layer 602 (e.g., a glass substrate, a borosilicate glass substrate, an alkaline earth boro-aluminosilicate substrate, a layer of SiO₂) including a first surface 602a.

The example clamp 600 can further include a plurality of burls 606 (e.g., CrN, AlN, or SiN burls) disposed over the first surface 602a of the first layer 602. For example, the plurality of burls 606 can be disposed on the first surface 602a of the first layer 602. A hardness of a subset of the plurality of burls 606 can be greater than about 6.0 GPa and, in some instances, greater than about 10.0 GPa, about 15.0 GPa, or even about 20.0 GPa. A thickness of the plurality of burls 606 can be greater than about 2.0 microns and, in some instances, greater than about 6.0 microns, 7.5 microns, or even about 10.0 microns. In some aspects, the plurality of burls 606 can include at least about thirty thousand burls. In some aspects, the plurality of burls 606 can be formed by patterning and etching a second layer (e.g., a CrN, AlN, or SiN layer) to form the plurality of burls 606.

Each burl in the plurality of burls 606 can include a second surface 606a and a third surface 606b opposite the second surface 606a. The third surface 606b of the burl can be disposed on the first surface 602a of the first layer 602.

Optionally, an object 608 (e.g., a wafer W or a patterning device MA) can be positioned over the plurality of burls 606. For example, a fourth surface 608a of the object 608 can be removable disposed (e.g., placed, positioned) on the second surface 606a of one or more of the plurality of burls 606. In some aspects, the plurality of burls 606 can be electrically conductive.

### Example Processes for Manufacturing a Surface Having Hard Burls

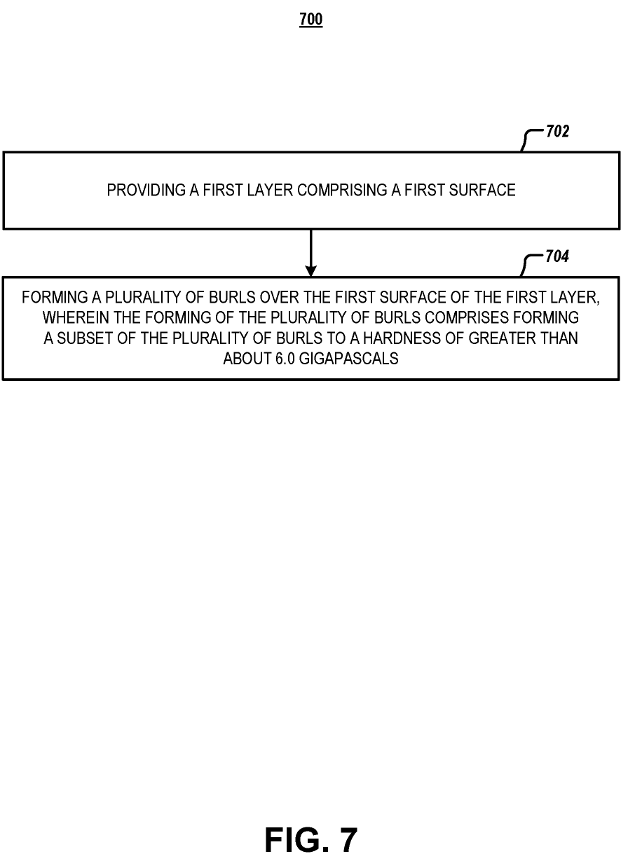

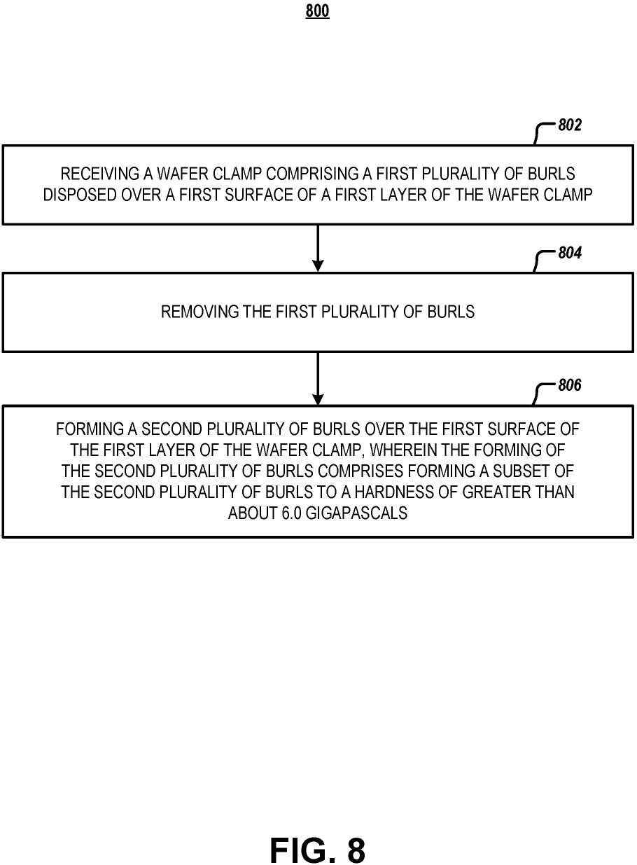

FIG. 7 is an example method 700 for manufacturing an apparatus according to some aspects of the present disclosure or portion(s) thereof. The operations described with reference to example method 700 can be performed by, or according to, any of the systems, apparatuses, components, techniques, or combinations thereof described herein, such as those described with reference to FIGS. 1A, 1B, 2, 3, 4, 5 and 6 above and FIG. 8 below.

At operation 702, the method can include providing a first layer including a first surface. In some aspects, the providing of the first layer can include providing a glass substrate, a borosilicate glass substrate, an alkaline earth boro-aluminosilicate substrate, a layer of SiO₂ (e.g., deposited via PECVD or any other suitable technique), or any other suitable layer.

At operation 704, the method can further include forming a plurality of burls over the first surface of the first layer. The forming of the plurality of burls can include forming a subset of the plurality of burls to a hardness of greater than about 6.0 GPa. In some aspects, the forming of the plurality of burls can include forming the plurality of burls of DLC. In some aspects, the forming of the plurality of burls can include forming the plurality of burls to a thickness of greater than about 2.0 micrometers, greater than about 5.0 micrometers, or greater than about 10.0 micrometers. In some aspects, the forming of the plurality of burls can include forming the plurality of burls of a material selected from the group consisting of AlN, SiN, or CrN. In some aspects, the forming of the plurality of burls can include forming at least about thirty thousand burls. In some aspects, the forming of the subset of the plurality of burls can include forming the subset of the plurality of burls to a hardness of greater than about 10.0 GPa, greater than about 15.0 GPa, or greater than about 20.0 GPa.

In some aspects, the forming the plurality of burls can include: forming a second layer including a second surface and a third surface opposite the second surface, wherein the third surface of the second layer is disposed on the first surface of the first layer; and forming a third layer including a fourth surface and a fifth surface opposite the fourth surface, wherein the fifth surface of the third layer is disposed on the second surface of the second layer, and wherein the forming of the plurality of burls can include patterning the third layer to form the plurality of burls. In some aspects, the forming of the second layer can include forming an adhesion layer. In some aspects, the forming of the adhesion layer can include forming the adhesion layer of at least one material selected from the group consisting of Cr or Al. In some aspects, the forming of the third layer can include forming the third layer of DLC. Optionally, in some aspects the method can further include curing the first layer and the plurality of burls at a temperature greater than about 350° C.

FIG. 8 is an example method 800 for manufacturing an apparatus according to some aspects of the present disclosure or portion(s) thereof. The operations described with reference to example method 800 can be performed by, or according to, any of the systems, apparatuses, components, techniques, or combinations thereof described herein, such as those described with reference to FIGS. 1A, 1B, 2, 3, 4, 5, 6 and 7 above.

At operation 802, the method can include receiving a wafer clamp, such as a wafer clamp with broken glass burls that has been returned from the field. The wafer clamp can include: a first layer including a first surface; and a first plurality of burls disposed over the first surface of the first layer. The first layer can include a glass substrate, a borosilicate glass substrate, an alkaline earth boro-aluminosilicate substrate, a layer of SiO₂ (e.g., deposited via PECVD or any other suitable technique), or any other suitable layer. The first plurality of burls can include a plurality of glass burls, some of which can be cracked or broken. In some aspects, the first plurality of burls can have a hardness of less than or equal to about 6.0 GPa.

At operation 804, the method can include removing the first plurality of burls. The removing of the first plurality of burls can include grinding the first plurality of burls, any intermediate layers between the first plurality of burls and the first layer. In some aspects, the removing of the first plurality of burls can further include grinding a portion of the first layer to form a modified first surface of the first layer. The removing of the first plurality of burls can further include polishing the first surface of the first layer (or, in some aspects, the modified first surface of the first layer formed as a result of grinding the portion of the first layer). In some aspects, after the first plurality of burls have been removed, the method can include performing a final polish to ensure that the surface of the first layer is a suitably free of defects. Subsequently, the method may include depositing (e.g., via a process such as PECVD) a thickness of SiO₂ or another dielectric material to return to the original thickness of the first layer (e.g., the borosilicate plate).

At operation 806, the method can further include forming a second plurality of burls over the first surface of the first layer (or, in some aspects, the modified first surface of the first layer). The forming of the second plurality of burls can include forming a subset of the second plurality of burls to a hardness of greater than about 6.0 GPa. In some aspects, the forming of the second plurality of burls includes forming the second plurality of burls of a material selected from the group consisting of DLC, AlN, SiN, or CrN. In some aspects, the forming of the second plurality of burls includes forming the second plurality of burls to a thickness of greater than about 2.0 micrometers, greater than about 5.0 micrometers, or greater than about 10.0 micrometers. In some aspects, the forming of the second plurality of burls includes forming at least about thirty thousand burls. In some aspects, the forming of the subset of the second plurality of burls includes forming the subset of the second plurality of burls to a hardness of greater than about 10.0 GPa, greater than about 15.0 GPa, or greater than about 20.0 GPa.

Other aspects of the invention are set out as in the following numbered clauses.
1. A method for manufacturing an apparatus, comprising:
   providing a first layer comprising a first surface; and
   forming a plurality of burls over the first surface of the first layer, wherein the forming of the plurality of burls comprises forming a subset of the plurality of burls to a hardness of greater than about 6.0 gigapascals (GPa).
2. The method of clause 1, wherein the providing of the first layer comprises providing a glass substrate.
3. The method of clause 1, wherein the forming of the plurality of burls comprises forming the plurality of burls of diamond-like carbon (DLC).
4. The method of clause 3, wherein the forming of the plurality of burls comprises forming the plurality of burls to a thickness of greater than about 2.0 micrometers.
5. The method of clause 3, wherein the forming of the plurality of burls comprises forming the plurality of burls to a thickness of greater than about 5.0 micrometers.
6. The method of clause 3, wherein the forming of the plurality of burls comprises forming the plurality of burls to a thickness of greater than about 10.0 micrometers.
7. The method of claim 1, wherein the forming of the plurality of burls comprises forming the plurality of burls of a material selected from the group consisting of aluminum nitride (AlN), silicon nitride (SiN), or chromium nitride (CrN).
8. The method of clause 1, wherein the forming of the plurality of burls comprises forming at least about thirty thousand burls.
9. The method of clause 1, wherein the forming of the subset of the plurality of burls comprises forming the subset of the plurality of burls to a hardness of greater than about 10.0 gigapascals (GPa).
10. The method of clause 1, wherein the forming of the subset of the plurality of burls comprises forming the subset of the plurality of burls to a hardness of greater than about 15.0 gigapascals (GPa).
11. The method of clause 1, wherein the forming of the subset of the plurality of burls comprises forming the subset of the plurality of burls to a hardness of greater than about 20.0 gigapascals (GPa).
12. The method of clause 1, wherein forming the plurality of burls comprises:
   forming a second layer comprising a second surface and a third surface opposite the second surface, wherein the third surface of the second layer is disposed on the first surface of the first layer; and
   forming a third layer comprising a fourth surface and a fifth surface opposite the fourth surface, wherein the fifth surface of the third layer is disposed on the second surface of the second layer,
   wherein the forming of the plurality of burls comprises patterning the third layer to form the plurality of burls.
13. The method of clause 12, wherein the forming of the second layer comprises forming an adhesion layer.
14. The method of clause 13, wherein the forming of the adhesion layer comprises forming the adhesion layer of at least one material selected from the group consisting of chromium (Cr) or aluminum (Al).
15. The method of clause 12, wherein the forming of the third layer comprises forming the third layer of diamond-like carbon (DLC).
16. A method for manufacturing an apparatus, comprising:
   receiving a wafer clamp, wherein the wafer clamp comprises
      a first layer comprising a first surface, and
      a first plurality of burls disposed over the first surface of the first layer;
   removing the first plurality of burls; and
   forming a second plurality of burls over the first surface of the first layer, wherein the forming of the second plurality of burls comprises forming a subset of the second plurality of burls to a hardness of greater than about 6.0 gigapascals (GPa).
17. The method of clause 16, wherein the forming of the second plurality of burls comprises forming the second plurality of burls of at least one material selected from the group consisting of diamond-like carbon (DLC), aluminum nitride (AlN), silicon nitride (SiN), or chromium nitride (CrN).
18. The method of clause 16, wherein the forming of the second plurality of burls comprises forming the second plurality of burls to a thickness of greater than about 2.0 micrometers.
19. An apparatus comprising:
   a first layer comprising a first surface; and
   a plurality of burls disposed over the first surface of the first layer, wherein a hardness of a subset of the plurality of burls is greater than about 6.0 gigapascals (GPa).
20. The apparatus of clause 19, wherein the plurality of burls comprises at least one material selected from the group consisting of diamond-like carbon (DLC), aluminum nitride (AlN), silicon nitride (SiN), or chromium nitride (CrN).

In some aspects, the forming the second plurality of burls includes: forming a second layer including a second surface and a third surface opposite the second surface, wherein the third surface of the second layer is disposed on the first surface of the first layer; and forming a third layer including a fourth surface and a fifth surface opposite the fourth surface, wherein the fifth surface of the third layer is disposed on the second surface of the second layer, and wherein the forming of the second plurality of burls includes patterning the third layer to form the second plurality of burls. In some aspects, the forming of the second layer includes forming an adhesion layer. In some aspects, the forming of the adhesion layer includes forming the adhesion layer of at least one material selected from the group consisting of Cr or Al. In some aspects, the forming of the third layer includes forming the third layer of DLC. Optionally, in some aspects the method can further include curing the first layer and the second plurality of burls at a temperature greater than about 350° C.

Although specific reference may be made in this text to the use of lithographic apparatus in the manufacture of ICs, it should be understood that the lithographic apparatuses described herein can have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein can be processed, before or after exposure, in for example a track unit (a tool that typically applies a layer of resist to a substrate and develops the exposed resist), a metrology unit and/or an inspection unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

It is to be understood that the phraseology or terminology herein is for the purpose of description and not of limitation, such that the terminology or phraseology of the present specification is to be interpreted by those skilled in relevant art(s) in light of the teachings herein.

The term “substrate” as used herein describes a material onto which material layers are added. In some aspects, the substrate itself can be patterned and materials added on top of it can also be patterned, or can remain without patterning.

The examples disclosed herein are illustrative, but not limiting, of the embodiments of this disclosure. Other suitable modifications and adaptations of the variety of conditions and parameters normally encountered in the field, and which would be apparent to those skilled in the relevant art(s), are within the spirit and scope of the disclosure.

Although specific reference may be made in this text to the use of the apparatus and/or system in the manufacture of ICs, it should be explicitly understood that such an apparatus and/or system has many other possible applications. For example, it can be employed in the manufacture of integrated optical systems, guidance and detection patterns for magnetic domain memories, LCD panels, thin-film magnetic heads, etc. The skilled artisan will appreciate that, in the context of such alternative applications, any use of the terms “reticle,” “wafer,” or “die” in this text should be considered as being replaced by the more general terms “mask,” “substrate,” and “target portion,” respectively.

While specific aspects of the disclosure have been described above, it will be appreciated that the aspects can be practiced otherwise than as described. The description is not intended to limit the embodiments of the disclosure.

It is to be appreciated that the Detailed Description section, and not the Background, Summary, and Abstract sections, is intended to be used to interpret the claims. The Summary and Abstract sections may set forth one or more but not all example embodiments as contemplated by the inventor(s), and thus, are not intended to limit the present embodiments and the appended claims in any way.

Some aspects of the disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific aspects of the disclosure will so fully reveal the general nature of the aspects that others can, by applying knowledge within the skill of the art, readily modify and/or adapt for various applications such specific aspects, without undue experimentation, without departing from the general concept of the present disclosure. Therefore, such adaptations and modifications are intended to be within the meaning and range of equivalents of the disclosed aspects, based on the teaching and guidance presented herein.

The breadth and scope of the present disclosure should not be limited by any of the above-described example aspects or embodiments, but should be defined only in accordance with the following claims and their equivalents.

1. A method for manufacturing an apparatus, comprising:
providing a first layer comprising a first surface; and
forming a plurality of burls over the first surface of the first layer, wherein the forming of the plurality of burls comprises forming a subset of the plurality of burls to a hardness of greater than about 6.0 gigapascals (GPa).

2. The method of claim 1, wherein the providing of the first layer comprises providing a glass substrate.

3. The method of claim 1, wherein the forming of the plurality of burls comprises forming the plurality of burls of diamond-like carbon (DLC).

4. The method of claim 3, wherein the forming of the plurality of burls comprises forming the plurality of burls to a thickness of greater than about 2.0 micrometers.

5. The method of claim 3, wherein the forming of the plurality of burls comprises forming the plurality of burls to a thickness of greater than about 5.0 micrometers.

6. The method of claim 3, wherein the forming of the plurality of burls comprises forming the plurality of burls to a thickness of greater than about 10.0 micrometers.

7. The method of claim 1, wherein the forming of the plurality of burls comprises forming the plurality of burls of a material selected from the group consisting of aluminum nitride (AlN), silicon nitride (SiN), or chromium nitride (CrN).

8. The method of claim 1, wherein the forming of the plurality of burls comprises forming at least about thirty thousand burls.

9. The method of claim 1, wherein the forming of the subset of the plurality of burls comprises forming the subset of the plurality of burls to a hardness of greater than about 10.0 gigapascals (GPa).

10. The method of claim 1, wherein the forming of the subset of the plurality of burls comprises forming the subset of the plurality of burls to a hardness of greater than about 15.0 gigapascals (GPa).

11. The method of claim 1, wherein the forming of the subset of the plurality of burls comprises forming the subset of the plurality of burls to a hardness of greater than about 20.0 gigapascals (GPa).

12. The method of claim 1, wherein forming the plurality of burls comprises:
forming a second layer comprising a second surface and a third surface opposite the second surface, wherein the third surface of the second layer is disposed on the first surface of the first layer; and
forming a third layer comprising a fourth surface and a fifth surface opposite the fourth surface, wherein the fifth surface of the third layer is disposed on the second surface of the second layer,
wherein the forming of the plurality of burls comprises patterning the third layer to form the plurality of burls.

13. The method of claim 12, wherein the forming of the second layer comprises forming an adhesion layer.

14. The method of claim 13, wherein the forming of the adhesion layer comprises forming the adhesion layer of at least one material selected from the group consisting of chromium (Cr) or aluminum (Al).

15. The method of claim 12, wherein the forming of the third layer comprises forming the third layer of diamond-like carbon (DLC).

16. A method for manufacturing an apparatus, comprising:
receiving a wafer clamp, wherein the wafer clamp comprises
a first layer comprising a first surface, and
a first plurality of burls disposed over the first surface of the first layer; removing the first plurality of burls; and
forming a second plurality of burls over the first surface of the first layer, wherein the forming of the second plurality of burls comprises forming a subset of the second plurality of burls to a hardness of greater than about 6.0 gigapascals (GPa).

17. The method of claim 16, wherein the forming of the second plurality of burls comprises forming the second plurality of burls of at least one material selected from the group consisting of diamond-like carbon (DLC), aluminum nitride (AlN), silicon nitride (SiN), or chromium nitride (CrN).

18. The method of claim 16, wherein the forming of the second plurality of burls comprises forming the second plurality of burls to a thickness of greater than about 2.0 micrometers.

19. An apparatus comprising:
a first layer comprising a first surface; and
a plurality of burls disposed over the first surface of the first layer, wherein a hardness of a subset of the plurality of burls is greater than about 6.0 gigapascals (GPa).

20. The apparatus of claim 19, wherein the plurality of burls comprises at least one material selected from the group consisting of diamond-like carbon (DLC), aluminum nitride (AlN), silicon nitride (SiN), or chromium nitride (CrN).
